(19) United States
(12) Patent Application Publication
(10) Pub. No.: US 2025/0234777 A1
(43) Pub. Date: Jul. 17, 2025

(54) SENSOR AND ELECTRONIC DEVICE

(71) Applicants: Samsung Electronics Co., Ltd., Suwon-si (KR); Imperial College Innovations Limited, London (GB)

(72) Inventors: Feifei FANG, Suwon-si (KR); Ji Seon KIM, London (GB); James DURRANT, London (GB); Song Yi PARK, London (GB); Kyung Bae PARK, Suwon-si (KR); Jeong Il PARK, Suwon-si (KR); Sungyoung YUN, Suwon-si (KR); Younhee LIM, Suwon-si (KR)

(73) Assignees: Samsung Electronics Co., Ltd., Suwon-si, Gyeonggi-do (KR); Imperial College Innovations Limited, London (GB)

(21) Appl. No.: 18/968,207

(22) Filed: Dec. 4, 2024

(30) Foreign Application Priority Data
Jan. 17, 2024 (KR) 10-2024-0007321

(51) Int. Cl. H10K 85/60; C07F 5/02; H10K 30/30; H10K 30/40; H10K 30/86

(52) U.S. Cl. CPC H10K 85/658; C07F 5/022; H10K 30/30; H10K 30/40; H10K 30/86

(57) ABSTRACT

A sensor includes an anode, a cathode, an organic photoelectric conversion layer between the anode and the cathode and including one type of organic light absorption semiconductor as a photoelectric conversion material and not including any other type of organic light absorption semiconductor, and a hole auxiliary layer between the anode and the organic photoelectric conversion layer and including a hole auxiliary material. An energy bandgap of the organic light absorption semiconductor is about 1.90 to about 2.20 eV. A HOMO energy level of the organic light absorption semiconductor is the same as or deeper than a HOMO energy level of the hole auxiliary material. A difference between the HOMO energy levels is greater than 0 eV and less than about 1.00 eV. A difference between a work function of the cathode and a LUMO energy level of the organic light absorption semiconductor is less than about 1.00 eV.

### CROSS-REFERENCE TO RELATED APPLICATION

This application claims priority to and the benefit of Korean Patent Application No. 10-2024-0007321 filed in the Korean Intellectual Property Office on Jan. 17, 2024, the entire contents of which are incorporated herein by reference.

### BACKGROUND

### 1. Field

Sensors and electronic devices are disclosed.

### 2. Description of the Related Art

Silicon photodiodes may be configured to absorb light in a wide wavelength spectrum and convert the absorbed light into electrical signals, and may be used with color filters to select light in a specific wavelength spectrum.

Organic materials may be configured to selectively absorb light of a specific wavelength spectrum depending on their molecular structure, and thus may be manufactured as organic photodiodes with wavelength selectivity without separate color filters. These organic photodiodes may be used as sensors with wavelength selectivity.

### SUMMARY

A sensor according to some example embodiments includes an organic photoelectric conversion layer configured to absorb light and convert the absorbed light into an electrical signal, and the organic photoelectric conversion layer may include two or more semiconductors with different electrical properties forming a pn junction. However, it is not easy to implement a sensor with the intended electrical characteristics by matching the material properties and/or processability of two or more semiconductors forming a pn junction.

Some example embodiments provide a sensor that may improve processability and implement desired electrical performance.

Some example embodiments provide an electronic device including the sensor.

According to some example embodiments, a sensor may include an anode, a cathode, an organic photoelectric conversion layer between the anode and the cathode, and a hole auxiliary layer between the anode and the organic photoelectric conversion layer. The organic photoelectric conversion layer may include one type of organic light absorption semiconductor as a photoelectric conversion material and may not include any other type of organic light absorption semiconductor of a different type of organic light absorption semiconductor, the one type of organic light absorption semiconductor is one of a p-type organic light absorption semiconductor or an n-type organic light absorption semiconductor. The hole auxiliary layer may include a hole auxiliary material, wherein an energy bandgap of the organic light absorption semiconductor is about 1.90 eV to about 2.20 eV, a highest occupied molecular orbital (HOMO) energy level of the organic light absorption semiconductor may be a same or deeper energy level in relation to a HOMO energy level of the hole auxiliary material, a difference between the HOMO energy level of the organic light absorption semiconductor and the HOMO energy level of the hole auxiliary material may be in a range of greater than 0 eV and less than about 1.00 eV, and a difference between a work function of the cathode and a LUMO energy level of the organic light absorption semiconductor is less than about 1.00 eV.

The organic photoelectric conversion layer may be a single layer formed of the organic light absorption semiconductor.

The sensor may further include an electron auxiliary layer between the cathode and the organic light absorption semiconductor and including an electron auxiliary material, and a difference between the LUMO energy level of the electron auxiliary material and the LUMO energy level of the organic light absorption semiconductor may be less than about 1.00 eV.

The sensor may be configured to exhibit a maximum external quantum efficiency (EQE) at a wavelength of about 500 nm to about 610 nm.

A full width at half maximum of the external quantum efficiency spectrum at 3V of the sensor may be about 30 nm to about 100 nm.

The organic light absorption semiconductor may be represented by Chemical Formula 1.

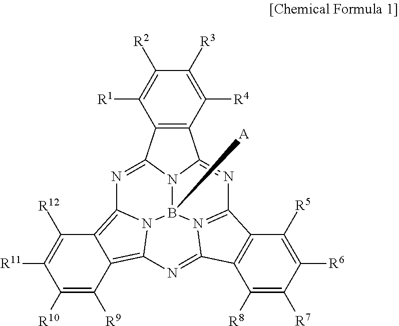

In Chemical Formula 1,

R¹ to R¹² may each independently be hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C6 to C30 aryloxy group, a substituted or unsubstituted C₃ to C30 heterocyclic group, a cyano group, a halogen, a halogen-containing group, or any combination thereof, and

A may be a halogen, a halogen-containing group, a substituted or unsubstituted C1 to C30 alkoxy group, a substituted or unsubstituted C6 to C30 aryloxy group, or any combination thereof.

At least one of R¹, R², R³, R⁴, R⁵, R⁶, R⁷, R⁸, R⁹, R¹⁰, R¹¹, R¹², or A may be a halogen or a halogen-containing group.

R¹ to R¹² may each independently be fluorine or a fluorine-containing group.

A may be a fluorine-substituted phenoxy group.

According to some example embodiments, a sensor may include an anode and a cathode, and an organic photoelectric conversion layer between the anode and the cathode and formed of an organic light absorption semiconductor represented by Chemical Formula 1.

The organic photoelectric conversion layer may not include any counterpart semiconductor for any pn junction with the organic light absorption semiconductor.

The organic photoelectric conversion layer may be a single layer formed of a single continuous phase of the organic light absorption semiconductor.

At least one of R¹, R², R³, R⁴, R⁵, R⁶, R⁷, R⁸, R⁹, R¹⁰, R¹¹, R¹², or A may be a halogen or a halogen-containing group.

R¹ to R¹² are each independently fluorine or fluorine-containing group.

A may be a fluorine-substituted phenoxy group.

The sensor may further include a hole auxiliary layer between the anode and the organic photoelectric conversion layer and including a hole auxiliary material, and a HOMO energy level of the organic light absorption semiconductor may be a same energy level or a deeper energy level in relation to a HOMO energy level of the hole auxiliary material, where a difference between the HOMO energy level of the organic light absorption semiconductor and the HOMO energy level of the hole auxiliary material may be in a range of greater than 0 eV and less than about 1.00 eV.

A difference between the work function of the cathode and a LUMO energy level of the organic light absorption semiconductor may be less than about 1.00 eV.

The sensor may further include an electron auxiliary layer between the cathode and the organic light absorption semiconductor and including an electron auxiliary material, and a difference between the LUMO energy level of the electron auxiliary material and the LUMO energy level of the organic light absorption semiconductor may be less than about 1.00 eV.

According to some example embodiments, an electronic device including the sensor is provided.

The processability of the sensor may be improved and the desired electrical characteristics may be easily achieved.

### BRIEF DESCRIPTION OF THE DRAWINGS

FIG. 1 is a cross-sectional view showing an example of a sensor according to some example embodiments,

FIG. 2 is a perspective view showing an example of an image sensor according to some example embodiments,

FIG. 3 is a cross-sectional view showing an example of the image sensor of FIG. 2 according to some example embodiments,

FIG. 4 is a cross-sectional view showing another example of the image sensor of FIG. 2 according to some example embodiments,

FIG. 5 is a perspective view showing another example of an image sensor according to some example embodiments,

FIG. 6 is a cross-sectional view showing an example of the image sensor of FIG. 5 according to some example embodiments,

FIG. 7 is a perspective view showing another example of an image sensor according to some example embodiments,

FIG. 8 is a cross-sectional view showing an example of the image sensor of FIG. 7 according to some example embodiments, and

FIG. 9 is a schematic view illustrating an example of a configuration of an electronic device according to some example embodiments.

### DETAILED DESCRIPTION

Hereinafter, example embodiments of the present inventive concepts will be described in detail so that a person skilled in the art would understand the same.

However, the inventive concepts may be embodied in many different forms and the inventive concepts are not to be construed as limited to the example embodiments set forth herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity, and the same or similar constituent elements are indicated by the same reference numeral throughout the specification.

Hereinafter, the terms “lower portion” and “upper portion” are for convenience of description and do not limit the positional relationship.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%)

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%). It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. It will be understood that elements and/or properties thereof described herein as being the “substantially” the same and/or identical encompasses elements and/or properties thereof that have a relative difference in magnitude that is equal to or less than 10%.

As used herein, when a definition is not otherwise provided, “substituted” refers to replacement of a hydrogen atom of a compound by a substituent selected from a halogen, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C30 heteroalkyl group, a C3 to C30 heterocyclic group, a C3 to C30 heteroarylalkyl group, a C3 to C30 cycloalkyl group, a C3 to C15 cycloalkenyl group, a C6 to C15 cycloalkynyl group, a C3 to C30 heterocycloalkyl group, and any combination thereof.

As used herein, when a definition is not otherwise provided, “aryl group” refers to a group including at least one hydrocarbon aromatic moiety. All elements of the hydrocarbon aromatic moiety have p-orbitals which form conjugation, for example a phenyl group, a naphthyl group, and the like, two or more hydrocarbon aromatic moieties may be linked by a sigma bond and may be, for example a biphenyl group, a terphenyl group, a quarterphenyl group, and the like, and two or more hydrocarbon aromatic moieties may be fused directly or indirectly to provide a non-aromatic fused ring, for example a fluorenyl group. The aryl group may include a monocyclic, polycyclic or fused polycyclic (i.e., rings sharing adjacent pairs of carbon atoms) functional group.

As used herein, when a definition is not otherwise provided, “heterocyclic group” may be a C2 to C30 heterocyclic group. The heterocyclic group refers to a cyclic group including 1 to 3 heteroatoms selected from N, O, S, Se, Te, P, and Si instead of carbon atom(s) in a cyclic group selected from an arene group (e.g., a C6 to C30 arene group, a C6 to C20 arene group, or a C6 to C10 arene group), an alicyclic hydrocarbon ring group (e.g., a C3 to C30 cycloalkyl group, a C3 to C20 cycloalkyl group, or a C3 to C10 cycloalkyl group), or a fused ring thereof. At least one carbon atom of the heterocyclic group may also be substituted with a thiocarbonyl group (C═S).

As used herein, when a definition is not otherwise provided, “fused ring” is a fused ring of two or more substituted or unsubstituted C5 to C30 hydrocarbon cyclic groups, a fused ring of two or more substituted or unsubstituted C₂ to C30 heterocyclic groups, or a fused ring of a substituted or unsubstituted C5 to C30 hydrocarbon cyclic group and a substituted or unsubstituted C₂ to C30 heterocyclic group (e.g., a fluorenyl group). Herein, the hydrocarbon cyclic group and the hetero cyclic group are as defined above.

As used herein, when a definition is not otherwise provided, “hetero” refers to one including 1 to 4 heteroatoms selected from N, O, S, Se, Te, Si, and P.

As used herein, “alkyl group” refers to a monovalent linear or branched saturated hydrocarbon group, for example, a methyl group, an ethyl group, a propyl group, an isopropyl group, an n-butyl group, an isobutyl group, a t-butyl group, a pentyl group, a hexyl group, and the like.

As used herein, when a definition is not otherwise provided, “alkoxy group” refers to a group represented by —OR, wherein R may be the alkyl group described above.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, a work function or an energy level is expressed as an absolute value from a vacuum level. In addition, when the work function or the energy level is referred to be deep, high, or large, it may have a large absolute value based on “0 eV” of the vacuum level while when the work function or the energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-2 (Hitachi) or AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

As used herein in connection with a numerical value, “about” or “substantially” includes an approximate range taking into account variations and errors within a normal range, for example, about 5%, 4%, 3%, 2%, or ±1%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof. When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

Hereinafter, a sensor according to some example embodiments will be described.

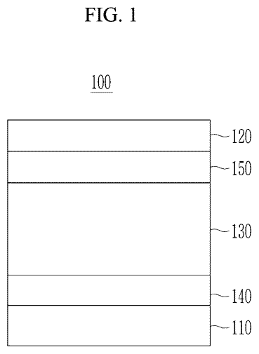

FIG. 1 is a cross-sectional view showing an example of a sensor according to some example embodiments.

The sensor 100 according to some example embodiments may be a photoelectric conversion diode configured to absorb light of a particular (or, alternatively, predetermined) wavelength spectrum and convert it (the absorbed light) into an electrical signal, for example, an organic photoelectric conversion diode including an organic light absorbing material.

Referring to FIG. 1, a sensor 100 according to some example embodiments includes an anode 110, a cathode 120, a hole auxiliary layer 140, an electron auxiliary layer 150, and an organic photoelectric conversion layer 130.

The substrate (not shown) may be under the anode 110 or on the cathode 120, or may be omitted. The substrate may be, for example, an inorganic substrate, such as a glass plate or a silicon wafer, or an organic substrate made of organic materials such as polycarbonate, polymethyl methacrylate, polyethylene terephthalate, polyethylene naphthalate, polyamide, polyethersulfone, or any combination thereof.

For example, the substrate may be a semiconductor substrate, for example a silicon substrate. The semiconductor substrate may include a circuit unit (not shown), and the circuit unit may include a transfer transistor (not shown) and/or a charge storage (not shown) integrated in the semiconductor substrate. The circuit unit may be electrically connected to the anode 110 or cathode 120.

At least one of the anode 110 or the cathode 120 may be a light transmitting electrode. The light transmitting electrode may be a transparent electrode or a semi-transmissive electrode. The transparent electrode may have a light transmittance of greater than or equal to about 85%, greater than or equal to about 90%, or greater than or equal to about 95% and less than or equal to about 100%, less than or equal to about 99%, or less than or equal to about 98%, and the semi-transmissive electrode may have a light transmittance of about 30% to about 85%, about 40% to about 80%, or about 40% to about 75%. The transparent electrode and the semi-transmissive electrode may include, for example, at least one of an oxide conductor, a carbon conductor, or a metal thin film. The oxide conductor may include, for example, one or more of indium tin oxide (ITO), indium zinc oxide (IZO), zinc tin oxide (ZTO), aluminum tin oxide (ATO), or aluminum zinc oxide (AZO), the carbon conductor may include one or more selected from graphene and carbon nanostructures, and the metal thin film may be a very thin film including aluminum (Al), magnesium (Mg), silver (Ag), gold (Au), magnesium-silver (Mg—Ag), magnesium-aluminum (Mg-AI), an alloy thereof, or any combination thereof.

Either the anode 110 or the cathode 120 may be a reflective electrode. The reflective electrode may include a reflective layer having a light transmittance of less than or equal to about 5% (e.g., about 0% to about 5%, about 0.01% to about 5%, about 0.1% to about 5%, or about 1% to about 5%) and/or a reflectance of greater than or equal to about 80% (e.g., about 80% to about 100%, about 80% to about 99%, about 80% to about 95%, about 80% to about 90%, or about 80% to about 85%), and the reflective layer may include an optically opaque material. The optically opaque material may include a metal, a metal nitride, or any combination thereof, for example silver (Ag), copper (Cu), aluminum (Al), gold (Au), titanium (Ti), chromium (Cr), nickel (Ni), an alloy thereof, a nitride thereof (e.g., TiN), or any combination thereof, but is not limited thereto. The reflective electrode may be formed of a reflective layer or may have a stacked structure of a reflective layer/transmissive layer or a transmissive layer/reflective layer/transmissive layer, and the reflective layer may be one layer or two or more layers.

As an example, the anode 110 and the cathode 120 may each be a light transmitting electrode, and either the anode 110 or the cathode 120 may be a light-receiving electrode on the side receiving light.

For example, the anode 110 may be a reflective electrode, the cathode 120 may be a light transmitting electrode, and the cathode 120 may be a light-receiving electrode.

For example, one of the anode 110 or the cathode 120 may be a semi-transmissive electrode, and the other of the anode 110 or the cathode 120 may be a reflective electrode. In this case, the sensor 100 may form (e.g., define) a microcavity structure. In the microcavity structure, reflection may occur repeatedly between the reflective electrode and the semi-transmissive electrode separated by a particular (or, alternatively, predetermined) optical path length (e.g., a distance between the semi-transmissive electrode and the reflective electrode) and light of a particular (or, alternatively, predetermined) wavelength spectrum may be enhanced to improve optical properties. Herein, light of a particular (or, alternatively, predetermined) wavelength spectrum may correspond to the wavelength spectrum of light absorbed by the organic photoelectric conversion layer 130, which will be described later.

For example, light with a particular (or, alternatively, predetermined) wavelength spectrum among the light incident on the sensor 100 may be repeatedly reflected between a semi-transmissive electrode and a reflective electrode and modified, and among the modified lights, light with a wavelength spectrum corresponding to the resonance wavelength of the microcavity may be strengthened and may exhibit amplified photoelectric conversion characteristics in a narrow wavelength region (where a wavelength region may be referred to herein interchangeably as a wavelength range). Accordingly, the sensor 100 may exhibit higher photoelectric conversion characteristics in a narrow wavelength range and thus may exhibit improved photoelectric conversion performance and/or photoelectric conversion efficiency in a particular wavelength range (e.g., reduced power consumption without compromising photoelectric conversion performance in the particular wavelength range).

The hole auxiliary layer 140 may be between (e.g., directly or indirectly between) the anode 110 and the organic photoelectric conversion layer 130, which will be described later, and may, for example, be in contact with one surface of the organic photoelectric conversion layer 130. The hole auxiliary layer 140 may be, for example, a hole injection layer (HIL), a hole transporting layer (HTL), an electron blocking layer (EBL), or any combination thereof.

The hole auxiliary layer 140 may include an organic material, an inorganic material, and/or an organic-inorganic material, for example a metal oxide such as molybdenum oxide, tungsten oxide, nickel oxide, or any combination thereof; a phthalocyanine compound such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris{N,-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/Camphor sulfonic acid), PANI/PSS (polyaniline/poly(4-styrenesulfonate)), NPB(N,N′-di(naphthalene-1-yl)-N,N′-diphenylbenzidine), triphenylamine containing polyether ketone (TPAPEK), 4-isopropyl-4′-methyldiphenyliodonium[Tetrakis(pentafluorophenyl)borate], HAT-CN(dipyrazino[2,3-f: 2′,3′-h]quinoxaline-2,3,6,7,10,11-hexacarbonitrile), a carbazole-based derivative such as N-phenylcarbazole or polyvinylcarbazole, a fluorene-based derivative, TPD (N,N′-bis(3-methylphenyl)-N,N′-diphenyl-[1,1-biphenyl]-4,4′-diamine), a triphenylamine derivative such as TCTA (4,4′,4″-tris(N-carbazolyl)triphenylamine), NPB(N,N′-di(naphthalene-1-yl)-N,N′-diphenyl-benzidine), TAPC(4,4′-Cyclohexylidene bis[N,N-bis(4-methylphenyl)benzenamine]), HMTPD (4,4′-Bis[N,N′-(3-tolyl)amino]-3,3′-dimethylbiphenyl), mCP (1,3-Bis(N-carbazolyl)benzene), or any combination thereof, but example embodiments are not limited thereto. In some example embodiments, the hole auxiliary layer 140 may be omitted from sensor 100.

The electron auxiliary layer 150 may be between (e.g., directly or indirectly between) the cathode 120 and the organic photoelectric conversion layer 130, which will be described later, and may, for example, be in contact with one surface of the organic photoelectric conversion layer 130. The electron auxiliary layer 150 may be, for example, an electron injecting layer (EIL), an electron transporting layer (ETL), a hole blocking layer (HBL), or any combination thereof.

The electron auxiliary layer 150 may include an electron auxiliary material. The electron auxiliary material may include, for example, a halogenated metal such as LiF, NaCl, CsF, RbCI, and/or Rbl; a lanthanide metal such as Yb; a metal such as calcium (Ca), potassium (K), aluminum (AI), or an alloy thereof; a metal oxide such as Li₂O and/or BaO; Liq (lithium quinolate), Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-Tri(1-phenyl-1 H-benzo[d]imidazol-2-yl)phenyl), BCP (2,9-dimethyl-4,7-diphenyl-1,10-phenanthroline), Bphen (4,7-diphenyl-1,10-phenanthroline), TAZ (3-(4-Biphenylyl)-4-phenyl-5-tertbutylphenyl-1,2,4-triazole), NTAZ (4-(naphthalen-1-yl)-3,5-diphenyl-4H-1,2,4-triazole), tBu-PBD (2-(4-Biphenylyl)-5-(4-tert-butylphenyl)-1,3,4-oxadiazole), BAlq (bis(2-methyl-8-quinolinolato-N1,08)-(1,1′-Biphenyl-4-olato)aluminum), Bebq2 (beryllium bis(benzoquinolin-10-olate), AND (9,10-di(naphthalene-2-yl)anthracene), BmPyPhB (1,3-bis[3,5-di(pyridin-3-yl)phenyl]benzene), or any combination thereof, but example embodiments are not limited thereto. The electron auxiliary layer 150 may be omitted.

The organic photoelectric conversion layer 130 may be between (e.g., directly or indirectly between) the anode 110 and the cathode 120. For example, one surface of the organic photoelectric conversion layer 130 may be in contact with the hole auxiliary layer 140, and the other, opposite surface of the organic photoelectric conversion layer 130 may be in contact with the electron auxiliary layer 150 or the cathode 120.

The organic photoelectric conversion layer 130 may be configured to absorb light in at least a portion of the wavelength region and convert it (the absorbed light) into an electrical signal, and may be configured to convert, for example, at least a portion of light in the blue wavelength region, light in the green wavelength region, light in the red wavelength region, and/or light in the infrared wavelength region into an electrical signal. Herein, selective absorption of light in the blue wavelength region, light in the green wavelength region, light in the red wavelength region, and/or light in the infrared wavelength region may mean that a maximum absorption wavelength (λ_{max,A}) of the absorption spectrum exists in any one relevant wavelength range of the wavelength ranges of about 380 nm to about 500 nm, about 500 nm to about 610 nm, about 610 nm to about 700 nm, or about 700 nm to about 3000 nm, and the absorption spectrum within the relevant wavelength range may be significantly greater than the absorption spectrum of other wavelength ranges. The “significantly higher” may mean that about 70% to about 100%, about 75% to about 100%, about 80% to about 100%, about 85% to about 100%, about 90% to about 100%, or about 95% to about 100% of the total area of the absorption spectrum may belong to (e.g., may be included in) the corresponding relevant wavelength range.

As an example, the organic photoelectric conversion layer 130 may have a maximum absorption wavelength (λ_{max,A}) in a wavelength range of about 500 nm to about 610 nm, that is, in the green wavelength spectrum. The maximum absorption wavelength (λ_{max,A}) of the organic photoelectric conversion layer 130 may belong to (e.g., may be included in) a wavelength range of about 510 nm to about 605 nm, about 510 nm to about 600 nm, about 510 nm to about 595 nm, about 520 nm to about 590 nm, about 520 nm to about 585 nm, or about 520 nm to about 580 nm.

The organic photoelectric conversion layer 130 may be configured to selectively absorb light in the above wavelength spectrum and photoelectrically convert the absorbed light. The organic photoelectric conversion layer 130 may be a single layer including (e.g., formed of, composed of, partially comprising or entirely comprising, etc.) one type of organic light absorption semiconductor alone as a photoelectric conversion material, or the organic photoelectric conversion layer 130 may be may be made of (e.g., formed of, composed of, partially comprising or entirely comprising, etc.) a single continuous phase of a single organic light absorption semiconductor, for example a single unitary piece of material partially or entirely comprising the single organic light absorption semiconductor. Therefore, the organic photoelectric conversion layer 130 may not include different types of photoelectric conversion materials, for example different types of organic light absorption semiconductors (at least one p-type semiconductor and at least one n-type semiconductor) generally required to form a pn junction.

For example, the organic photoelectric conversion layer 130 may include one type of organic light absorption semiconductor as a photoelectric conversion material and may not include any other type of organic light absorption semiconductor of a different type of organic light absorption semiconductor, where the one type of organic light absorption semiconductor is one of a p-type organic light absorption semiconductor or an n-type organic light absorption semiconductor. For example, the organic photoelectric conversion layer 130 may not include different types of organic light absorption semiconductors (e.g., may not include both a p-type organic light absorption semiconductor and an n-type organic light absorption semiconductor). For example, the organic photoelectric conversion layer 130 may be a single layer including one type of organic light absorption semiconductor and not including (e.g., excluding) any organic light absorption semiconductors of another type of organic light absorption semiconductor. For example, the organic photoelectric conversion layer 130 may be a single layer including at least one p-type organic light absorption semiconductor or at least one organic light absorption n-type semiconductor. For example, the organic photoelectric conversion layer 130 may be a single layer including at least one p-type organic light absorption semiconductor and not including any n-type organic light absorption semiconductors. In another example, the organic photoelectric conversion layer 130 may be a single layer including at least one n-type organic light absorption semiconductor and not including any p-type organic light absorption semiconductors. In some example embodiments, the organic photoelectric conversion layer 130 may include (e.g., partially or entirely comprise) a single (sole) organic light absorption semiconductor that is one of a p-type organic light absorption semiconductor or an n-type organic light absorption semiconductor may not include any other organic light absorption semiconductors. In some example embodiments, the organic photoelectric conversion layer 130 may include (e.g., may partially or entirely comprise) multiple organic light absorption semiconductors of a same type (e.g., multiple organic light absorption semiconductors that are each a p-type organic light absorption semiconductor or are each an n-type organic light absorption semiconductor) and may not include any organic light absorption semiconductors of a different type. For example, in example embodiments where the organic photoelectric conversion layer 130 includes multiple p-type organic light absorption semiconductors, the organic photoelectric conversion layer 130 may not include any n-type organic light absorption semiconductors. In another example, in example embodiments where the organic photoelectric conversion layer 130 includes multiple n-type organic light absorption semiconductors, the organic photoelectric conversion layer 130 may not include any p-type organic light absorption semiconductors. For example, the organic photoelectric conversion layer 130 may include a single organic light absorption semiconductor that is one of a p-type semiconductor or an n-type semiconductor and may not include any counter semiconductor (also referred to herein as a counterpart semiconductor) for forming a pn junction with the single organic light absorption semiconductor included in the organic photoelectric conversion layer 130.

Therefore, unlike a typical photoelectric conversion layer that includes both a p-type semiconductor and an n-type semiconductor, the organic light absorption semiconductor alone (e.g., the sole organic light absorption semiconductor, or the one type of organic light absorption semiconductor included in the organic photoelectric conversion layer 130) may have electrical characteristics that may stably transmit both holes and electrons generated by absorbing light to the anode 110 and cathode 120, respectively. For example, the organic photoelectric conversion layer 130 may be configured to stably transmit both holes and electrons generated by absorbing light to the anode 110 and cathode 120, respectively, based on including one type (e.g., of p-type or n-type semiconductor) of organic light absorption semiconductor as a photoelectric conversion material therein (e.g., including a single organic light absorption semiconductor or multiple organic light absorption semiconductor of the same type) and not including any other type (e.g., of p-type or n-type semiconductor) of organic light absorption semiconductor therein (e.g., not including any counter semiconductor for forming a pn junction with one or more organic light absorption semiconductors included in the organic photoelectric conversion layer), and thus effective electrical matching may be achieved with adjacent layers, thereby improving the processability of the sensor (e.g., of semiconductors forming a pn junction between the organic photoelectric conversion layer 130 and a different layer) and thereby improving the reliability the sensor 100 having intended electrical characteristics. As a result, the sensor 100 may have improved reliability of electrical characteristics, and thus improved reliability and/or consistency of desired image sensing performance corresponding to the electrical characteristics of the sensor 100 corresponding to at least the organic photoelectric conversion layer 130 thereof.

In some example embodiments, the highest occupied molecular orbital (HOMO) energy level of the organic light absorption semiconductor of the organic photoelectric conversion layer 130 may be the same as or deeper than (e.g., a same or deeper energy level in relation to) the HOMO energy level of the hole auxiliary material of the hole auxiliary layer 140, and a difference (e.g., an absolute value of the difference) between the HOMO energy level of the organic light absorption semiconductor and the HOMO energy level of the hole auxiliary material of the hole auxiliary layer 140 may be less than about 1.00 eV (e.g., the difference may be in a range of greater than 0 eV and less than about 1.00 eV). Within the above range, the difference between the HOMO energy level of the organic light absorption semiconductor and the HOMO energy level of the hole auxiliary material of the hole auxiliary layer 140 may be less than or equal to about 0.80 eV or less than or equal to about 0.60 eV. For example, the difference between the HOMO energy level of the organic light absorption semiconductor and the HOMO energy level of the hole auxiliary material of the hole auxiliary layer 140 may be in a range of about 0 eV to about 1.00 eV, about 0 eV to about 0.80 eV, or about 0 eV to about 0.60 eV.

For example, a difference between the work function of the cathode 120 and/or the lowest unoccupied molecular orbital (LUMO) energy level of the electron auxiliary material of the electron auxiliary layer 150 and the LUMO energy level of the organic light absorption semiconductor may be less than about 1.00 eV (e.g., the difference may be in a range of greater than 0 eV and less than about 1.00 eV). Within the above range, the difference between the work function of the cathode 120 and/or the LUMO energy level of the electron auxiliary material of the electron auxiliary layer 150 and the LUMO energy level of the organic light absorption semiconductor may be about 0 eV to about 0.80 eV or about 0 eV to about 0.60 eV.

As an example, the HOMO energy level and LUMO energy level of the organic light absorption semiconductor may satisfy the above-mentioned range and further have an energy bandgap of about 1.90 eV to about 2.20 eV. The organic light absorption semiconductor that simultaneously satisfies the HOMO energy level, LUMO energy level, and energy bandgap may be configured to selectively absorb light in the green wavelength spectrum and stably transfer holes and electrons generated from the absorbed light to the anode 110 and cathode 120, alone without a separate counterpart semiconductor (e.g., counter semiconductor).

Accordingly, the electrical characteristics of the sensor 100 or the organic photoelectric conversion layer 130 may be determined by (e.g., may be based on) the light absorption characteristics of the organic light absorption semiconductor alone (e.g., not based on light absorption characteristics of any counter semiconductors of a different type of organic light absorption semiconductor) and the resulting electrical characteristics. For example, when the organic photoelectric conversion layer 130 has a maximum absorption wavelength (λ_{max,A}) in the wavelength range of about 500 nm to 610 nm, that is, in the green wavelength spectrum, as described above, the maximum external quantum efficiency wavelength (λ_{max,EQE}) of the sensor 100 (e.g., the wavelength at which the sensor is configured to exhibit a maximum external quantum efficiency (EQE)) may also be in the wavelength range of about 500 nm to about 610 nm, that is, in the green wavelength spectrum, and within the above range, about 510 nm to about 605 nm, about 510 nm to about 600 nm, about 510 nm to about 595 nm, about 520 nm to about 590 nm, about 520 nm to about 585 nm, or about 520 nm to about 580 nm.

For example, the difference between the maximum absorption wavelength (λ_{max,A}) of the organic light absorption semiconductor and the maximum external quantum efficiency wavelength (λ_{max,EQE}) of the sensor 100 may be less than or equal to about 20 nm, and within the above range, less than or equal to about 15 nm, less than or equal to about 10 nm, or less than or equal to about 5 nm. The maximum absorption wavelength (λ_{max,A}) of the organic light absorption semiconductor and the maximum external quantum efficiency wavelength (λ_{max,EQE}) of the sensor 100 may be, for example, equal or substantially equal to each other. For example, the difference between the maximum external quantum efficiency wavelength (λ_{max,EQE}) of the sensor 100 and the maximum absorption wavelength (λ_{max,A}) of the organic light absorption semiconductor may be ±20 nm, ±15 nm, ±10 nm, ±5 nm, ±3 nm, or ±1 nm.

Meanwhile, the organic light absorption semiconductor may be a depositable organic light absorption semiconductor that may be vaporized (sublimated) and deposited at a particular (or, alternatively, predetermined) temperature. For example, the sublimation temperature (Ts) of the organic light absorption semiconductor may be less than or equal to about 350° C., and within the above range, less than or equal to about 330° C., less than or equal to about 300° C., less than or equal to about 280° C., less than or equal to about 270° C., about 100° C. to about 350° C., about 100° C. to about 330° C., about 100° C. to about 300° C., about 100° C. to about 290° C., about 100° C. to about 280° C., about 100° C. to about 270° C., about 100° C. to about 260° C., about 100° C. to about 250° C., about 150° C. to about 350° C., about 150° C. to about 330° C., about 150° C. to about 300° C., about 150° C. to about 290° C., about 150° C. to about 280° C., about 150° C. to about 270° C., about 150° C. to about 260° C., about 150° C. to about 250° C., about 200° C. to about 350° C., about 200° C. to about 330° C., about 200° C. to about 300° C., about 200° C. to about 290° C., about 200° C. to about 280° C., about 200° C. to about 270° C., about 200° C. to about 260° C., or about 200° C. to about 250° C. The organic photoelectric conversion layer 130 may be stably deposited considering only the sublimation temperature of the organic light absorption semiconductor.

The organic photoelectric conversion layer 130 may include one type of organic light absorption semiconductor alone (e.g., the organic photoelectric conversion layer 130 may include one type of organic light absorption semiconductor that is one of a p-type organic light absorption semiconductor or an n-type organic light absorption semiconductor and may not include any organic light absorption semiconductors of the other type of a p-type organic light absorption semiconductor or an n-type organic light absorption semiconductor) with the above-mentioned optical properties, electrical characteristics, and stable deposition temperature, so that, unlike a typical photoelectric conversion layer that includes both a p-type semiconductor and an n-type semiconductor, deterioration in the performance of the organic photoelectric conversion layer 130 due to different optical properties, electrical characteristics, and deposition conditions of the p-type semiconductor and the n-type semiconductor may be reduced, minimized, or prevented. As a result, the sensor 100 may exhibit improved reliability and/or performance (e.g., image sensing performance and/or image generating performance).

As an example, the organic photoelectric conversion layer 130 including one type of organic light absorption semiconductor alone (e.g., an organic photoelectric conversion layer 130 including one type of organic light absorption semiconductor that is one of a p-type organic light absorption semiconductor or an n-type organic light absorption semiconductor and not including any organic light absorption semiconductors of the other type of a p-type organic light absorption semiconductor or an n-type organic light absorption semiconductor) may have higher wavelength selectivity compared to a typical photoelectric conversion layer including both a p-type semiconductor and an n-type semiconductor for a pn junction. As a result, the sensor 100 may exhibit improved image sensing performance and/or image generating performance. In general, a photoelectric conversion layer including both a p-type semiconductor and an n-type semiconductor may exhibit light absorption characteristics over a wide wavelength range by adding the light absorption characteristics of the p-type semiconductor and the n-type semiconductor in parallel, and as a result, wavelength selectivity, which exhibits higher absorption characteristics in the narrow wavelength range intended and required by the sensor 100, may be reduced. Herein, the wavelength selectivity for light absorption may be expressed as the full width half maximum (FWHM_{A}) of the absorption spectrum, and the full width at half maximum (FWHM_{A}) of the absorption spectrum may be a width of the wavelength corresponding to half of the absorption intensity at the maximum absorption wavelength (λ_{max,A}).

In addition, due to this reduced wavelength selectivity, higher external quantum efficiency (EQE) characteristics may be exhibited over a wide wavelength range, and as a result, the external quantum efficiency (EQE) wavelength selectivity, which selectively exhibits higher external quantum efficiency (EQE) in the narrow wavelength range intended and required by the sensor 100, may also be reduced. Herein, the external quantum efficiency (EQE) wavelength selectivity may be expressed as the half width of the EQE spectrum (FWHM_{EQE}), and the full width at half maximum (FWHM_{EQE}) of the external quantum efficiency (EQE) spectrum may be a width of a wavelength corresponding to half of the external quantum efficiency at the wavelength (λ_{max,EQE}) representing the maximum external quantum efficiency (EQEₘₐₓ).

For example, the half width of the external quantum efficiency (EQE) spectrum at 3V of the sensor 100 may be less than or equal to about 100 nm, and within the above range, about 30 nm to about 100 nm, about 30 nm to about 95 nm, about 30 nm to about 90 nm, about 30 nm to about 85 nm, about 30 nm to about 80 nm, about 30 nm to about 75 nm, or about 30 nm to about 70 nm.

For example, in example embodiments where the organic photoelectric conversion layer 130 includes one organic light absorption semiconductor alone (e.g., an organic photoelectric conversion layer 130 including one organic light absorption semiconductor that is one of a p-type organic light absorption semiconductor or an n-type organic light absorption semiconductor and not including any organic light absorption semiconductors of the other type of a p-type organic light absorption semiconductor or an n-type organic light absorption semiconductor), the electrical characteristics of the sensor 100 may be predicted based on the electrical characteristics of the one organic light absorption semiconductor alone (e.g., the electrical characteristics of the sensor 100 may correspond to the electrical characteristics of the one organic light absorption semiconductor alone), and thus it is possible to implement a stable and predictable organic photoelectric conversion layer 130 and sensor 100 without having to consider the individual electrical characteristics of the p-type semiconductor and the n-type semiconductor and the variable electrical characteristics depending on the composition ratio of the p-type semiconductor and the n-type semiconductor. As a result, the sensor 100 may be configured to have particular desired electrical characteristics with improved reliability, accuracy, and/or precision, based on the electrical characteristics of the organic light absorption semiconductor alone.

As an example, the organic photoelectric conversion layer 130 including one organic light absorption semiconductor alone (e.g., including a single organic light absorption semiconductor and not including any other organic light absorption semiconductors) may be formed by considering only the deposition conditions of the organic light absorption semiconductor, and thus, unlike a typical photoelectric conversion layer that includes both a p-type semiconductor and an n-type semiconductor, the organic photoelectric conversion layer 130 is stably formed under deposition conditions appropriate for an organic light absorption semiconductor without having to consider different deposition temperatures and deposition rates of heterogeneous materials. Therefore, the process may be simplified and the organic photoelectric conversion layer 130 and sensor 100 with higher process stability may be formed, thereby enabling formation of a sensor 100 having improved reliability and/or performance.

As an example, the one type of organic light absorption semiconductor may include an organic light absorption semiconductor that may be a compound represented by Chemical Formula 1.

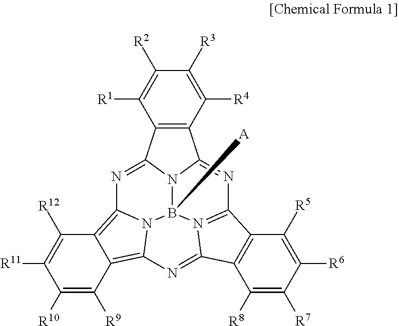

In Chemical Formula 1,

R¹ to R¹² may each independently be hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C6 to C30 aryloxy group, a substituted or unsubstituted C₃ to C30 heterocyclic group, a cyano group, a halogen, a halogen-containing group, or any combination thereof, and

A may be halogen, a halogen-containing group, a substituted or unsubstituted C1 to C30 alkoxy group, a substituted or unsubstituted C6 to C30 aryloxy group, or any combination thereof.

For example, at least one of R¹ to R¹² and/or A (e.g., at least one of R¹, R², R³, R⁴, R⁵, R⁶, R⁷, R⁸, R⁹, R¹⁰, R¹¹, R¹², or A) may be a halogen selected from F, Cl, Br, and I or a halogen-containing group including the halogen. The halogen-containing group may include, for example, a C1 to C30 alkyl group substituted with at least one halogen, a C1 to C30 alkoxy group substituted with at least one halogen, a C6 to C30 aryl group substituted with at least one halogen, a C6 to C30 aryloxy group substituted with at least one halogen, a C3 to C30 heterocyclic group substituted with at least one halogen, or any combination thereof. In this way, by introducing an appropriate substituent (R¹ to R¹² and/or A) into the organic light absorption semiconductor represented by Chemical Formula 1, electrical characteristics of the aforementioned organic light absorption semiconductor may be adjusted while the deposition temperature may be lowered to increase process stability.

For example, R¹ to R¹² may each independently be a halogen or a halogen-containing group. For example, R¹ to R¹² may each independently be a fluorine or a fluorine-containing group.

As an example, A may be a halogen-substituted phenoxy group, for example, a fluorine-substituted phenoxy group.

As an example, the organic light absorption semiconductor may be one of the compounds listed in Group 1, but is not limited thereto.

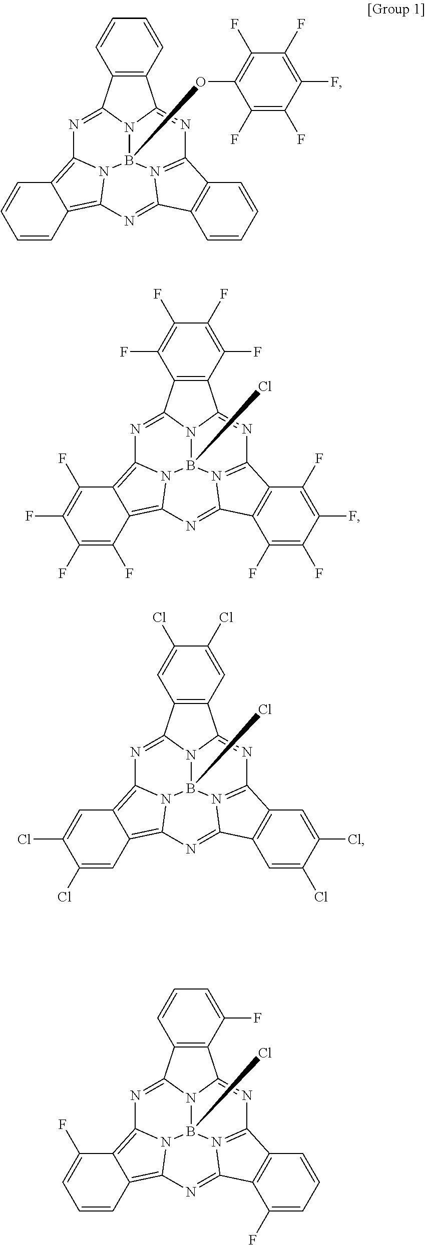

A thickness of the organic photoelectric conversion layer 130 may be about 1 nm to about 500 nm, and within the above range, about 5 nm to about 300 nm or about 10 nm to about 200 nm. By having a thickness in the above range, a single organic light absorption semiconductor may be configured to effectively absorb light and effectively separate and transfer holes and electrons, thereby realizing higher (e.g., improved) photoelectric conversion efficiency, reduced power consumption without compromising photoelectric conversion performance, or the like.

The sensor 100 may further include an anti-reflection layer (not shown) under the anode 110 or on the cathode 120. For example, when the anode 110 is a light-receiving electrode, the anti-reflection layer may be under the anode 110. For example, when the cathode 120 is a light-receiving electrode, the anti-reflection layer may be on the cathode 120.

The anti-reflection layer may be on the side where light is incident to further improve light absorption by lowering the reflectivity of incident light. The anti-reflection layer may include, for example, a material having a refractive index of about 1.6 to about 2.5, and may include, for example, at least one of a metal oxide, a metal sulfide, or an organic material having a refractive index in the above range. The anti-reflection layer may include, for example, a metal oxide such as aluminum-containing oxide, molybdenum-containing oxide, tungsten-containing oxide, vanadium-containing oxide, rhenium-containing oxide, niobium-containing oxide, tantalum-containing oxide, titanium-containing oxide, nickel-containing oxide, copper-containing oxide, cobalt-containing oxide, manganese-containing oxide, chromium-containing oxide, tellurium-containing oxide, or any combination thereof; a metal sulfide such as zinc sulfide; or an organic material such as an amine derivative, but example embodiments are not limited thereto.

The sensor 100 may further include a focusing lens (not shown). The focusing lens may control the direction of incident light at the location where the light enters and focus the light at one region. The focusing lens may have a shape of, for example, a cylinder or a hemisphere, but is not limited thereto.

When light is incident on the sensor 100 from the anode 110 or the cathode 120 and the organic photoelectric conversion layer 130 absorbs light in a particular (or, alternatively, predetermined) wavelength region, excitons may be generated inside the sensor 100. The excitons are separated into holes and electrons in the organic photoelectric conversion layer 130, the separated holes move toward the anode 110, and the separated electrons move toward the cathode 120, allowing current to flow.

The sensor 100 may be, for example, included in an image sensor.

The image sensor may be, for example, a CMOS image sensor.

Biometric sensors may include, for example, fingerprint sensors, iris recognition sensors, distance sensors, photoplethysmography (PPG) sensor devices, electroencephalogram (EEG) sensor devices, electrocardiogram (ECG) sensor devices, blood pressure (BP) sensors, sensor devices, electromyography (EMG) sensor devices, blood glucose (BG) sensor devices, accelerometer devices, RFID antenna devices, inertial sensor devices, activity sensor devices, strain sensor devices, motion sensor devices, or any combination thereof, but example embodiments are not limited thereto.

As an example, the aforementioned sensor 100 may be included in an image sensor.

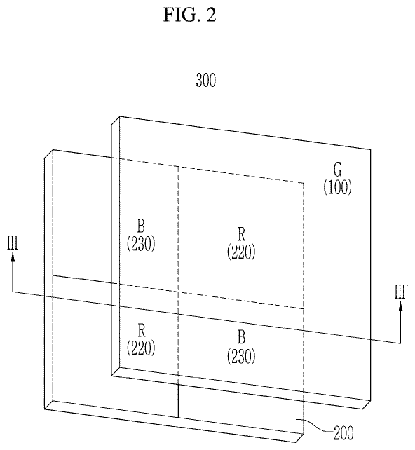

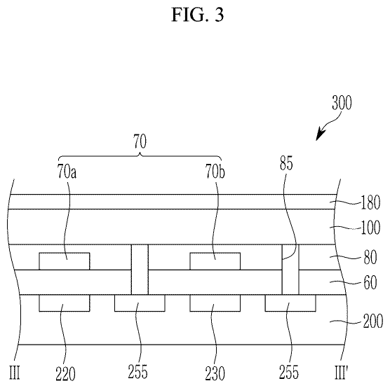

FIG. 2 is a perspective view showing an example of an image sensor 300 according to some example embodiments and FIG. 3 is a cross-sectional view along view line III-III′ in FIG. 2, showing an example of the image sensor 300 of FIG. 2 according to some example embodiments.

Referring to FIG. 2, the image sensor 300 according to some example embodiments may be a stacked sensor in which a semiconductor substrate 200 and the aforementioned sensor 100 are stacked, and the semiconductor substrate 200 includes a first photodiode 220 and a second photodiode 230 that overlap the sensor 100 (e.g., overlap in a vertical direction extending perpendicular to an in-plane direction of the semiconductor substrate 200 as shown). FIG. 2 illustrates an example of a repeated unit pixel group in the image sensor 300, and this unit pixel group is repeatedly arranged along rows and/or columns. In FIG. 2, as an example, a 2×2 array of unit pixels in which two red pixels (R) and two blue pixels (B) are arranged on the semiconductor substrate 200 is illustrated, but the present inventive concepts are not limited thereto.

The first photodiode 220 and the second photodiode 230 may each be integrated in the semiconductor substrate 200 and may be configured to absorb light of different wavelength spectra filtered by the color filter layer 70, which will be described later and photoelectrically convert light of different wavelength spectra.

The wavelength spectrum of light photoelectrically converted in the sensor 100 may be different from the wavelength spectrum of light photoelectrically converted in the first photodiode 220 and the second photodiode 230. For example, the wavelength spectrum of light photoelectrically converted in the first photodiode 220, the wavelength spectrum of light photoelectrically converted in the second photodiode 230, and the wavelength spectrum of light photoelectrically converted in the sensor 100 may be different from each other and may each be one of light in a red wavelength spectrum, light in a green wavelength spectrum, or light in a blue wavelength spectrum. For example, the first photodiode 220 may be configured to photoelectrically convert light in the red wavelength spectrum R, the second photodiode 230 may be configured to photoelectrically convert light in the blue wavelength spectrum B, and the sensor 100 may be configured to photoelectrically convert light in the green wavelength spectrum G.

Referring to FIG. 3, the image sensor 300 according to some example embodiments includes a semiconductor substrate 200, a lower insulation layer 60, a color filter layer 70, an upper insulation layer 80, a sensor 100, and an encapsulation layer 180.

The semiconductor substrate 200 may be a semiconductor substrate, and the first and second photodiodes 220 and 230, a transfer transistor (not shown), and a charge storage 255 are integrated therein. The first or second photodiode 220 or 230, the transfer transistor and/or the charge storage 255 may be integrated for each pixel, and as shown in the drawing, the first photodiode 220 may be included in the red pixel R and the second photodiode 230 may be included in the blue pixel B. The charge storage 255 is electrically connected to the sensor 100.

A metal wire (not shown) and a pad (not shown) are formed under or on the semiconductor substrate 200. In order to decrease signal delay, the metal wire and pad may be made of a metal having low resistivity, for example, aluminum (AI), copper (Cu), silver (Ag), or an alloy thereof, but is not limited thereto.

The lower insulation layer 60 is formed on the semiconductor substrate 200.

The lower insulation layer 60 may be made of an inorganic insulating material such as a silicon oxide and/or a silicon nitride, or a low dielectric constant (low K) material such as SiC, SiCOH, SiCO, and SiOF. The lower insulation layer 60 has a trench 85 exposing charge storage 255. The trench 85 may be filled with filler material.

A color filter layer 70 is formed on the lower insulation layer 60. The color filter layer 70 includes a red filter 70a formed in the red pixel R and a blue filter 70b formed in the blue pixel B. However, example embodiments are not limited thereto, and a cyan filter, a magenta filter, and/or a yellow filter may be included instead of the red filter 70a and/or the blue filter 70b, or may be included in addition to the red filter 70a and the blue filter 70b. In some example embodiments, including the example embodiments shown in FIGS. 2 and 3, an example without a green filter is described, but in some example embodiments, a green filter may be included in the image sensor 300.

An upper insulation layer 80 is formed on the color filter layer 70. The upper insulation layer 80 removes a level difference caused by the color filter layer 70 and flattens it. The upper insulation layer 80 may be made of an inorganic insulating material such as a silicon oxide and/or a silicon nitride, or a low dielectric constant (low K) material such as SiC, SiCOH, SiCO, and SiOF. The upper insulation layer 80 and lower insulation layer 60 have a contact hole (not shown) exposing the pad and a trench 85 exposing the charge storage 255.

The aforementioned sensor 100 is formed on the upper insulation layer 80. A detailed description of the sensor 100 is as described above. One of the anode 110 or the cathode 120 of the sensor 100 may be electrically connected to the charge storage 255, and the other of the anode 110 or the cathode 120 of the sensor 100 may be a light-receiving electrode. For example, the anode 110 of the sensor 100 may be electrically connected to the charge storage 255 and the cathode 120 of the sensor 100 may be a light-receiving electrode.

The encapsulation layer 180 may protect the image sensor 300 and may include one or two or more layers of thin film including organic materials, inorganic materials, organic and inorganic materials, or any combination thereof. The encapsulation layer 180 may include, for example, a glass plate, a metal thin film, an organic film, an inorganic film, an organic/inorganic film, or any combination thereof. The organic film may include, for example, an acrylic resin, a (meth)acrylic resin, a polyisoprene, a vinyl resin, an epoxy resin, a urethane resin, a cellulose resin, a perylene resin, or any combination thereof, but is not limited thereto. The inorganic film may include, for example oxide, nitride, and/or oxynitride, for example silicon oxide, silicon nitride, silicon oxynitride, aluminum oxide, aluminum nitride, aluminum oxynitride, zirconium oxide, zirconium nitride, zirconium oxynitride, titanium oxide, titanium nitride, titanium oxynitride, hafnium oxide, hafnium nitride, hafnium oxynitride, tantalum oxide, tantalum nitride, tantalum oxynitride, lithium fluoride, or any combination thereof, but is not limited thereto. The organic/inorganic film may include, for example, polyorganosiloxane, but is not limited thereto. The encapsulation layer 180 may be one or two or more layers. The encapsulation layer 180 may be omitted.

Focusing lens (not shown) may be further formed on the sensor 100 (or encapsulation layer 180). The focusing lens may control a direction of incident light and gather the light in one region. The focusing lens may have a shape of, for example, a cylinder or a hemisphere, but is not limited thereto.

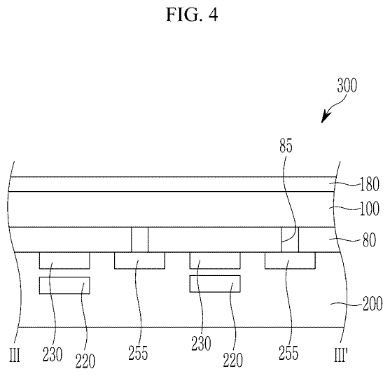

FIG. 4 is a cross-sectional view showing another example of the image sensor of FIG. 2 according to some example embodiments. FIG. 4 may be a cross-sectional view along view line III-III′ in FIG. 2 according to some example embodiments.

Referring to FIG. 4, the image sensor 300 according to an example includes a semiconductor substrate 200 integrated with first and second photodiodes 220 and 230, a transfer transistor (not shown), and a charge storage 255; an upper insulation layer 80; a sensor 100; and an encapsulation layer 180, like some example embodiments, including the example embodiments shown in FIG. 3.

However, in the image sensor 300 according to some example embodiments, including the example embodiments shown in FIG. 4, unlike some example embodiments, including the example embodiments shown in FIG. 3, the first and second photodiodes 220 and 230 are disposed perpendicular to the in-plane direction of the semiconductor substrate 200 (e.g., parallel to the thickness direction of the semiconductor substrate 200) and the color filter layer 70 is omitted. The first and second photodiodes 220 and 230 are electrically connected to a charge storage (not shown) and may be transferred by a transfer transistor. The first and second photodiodes 220 and 230 may be configured to selectively absorb light in each wavelength region depending on the stacking depth.

The sensor 100 is as described above. One of the anode 110 or the cathode 120 of the sensor 100 may be a light-receiving electrode, and the other of the anode 110 or the cathode 120 of the sensor 100 may be electrically connected to the charge storage 255.

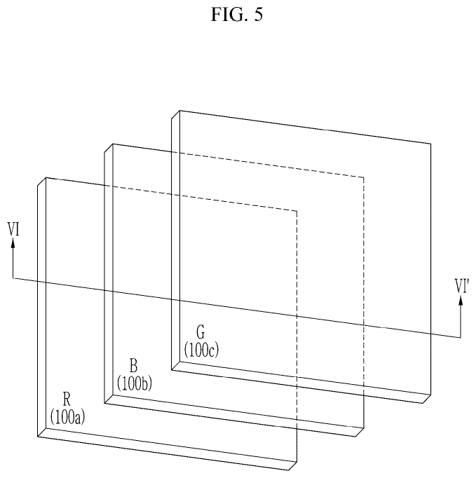

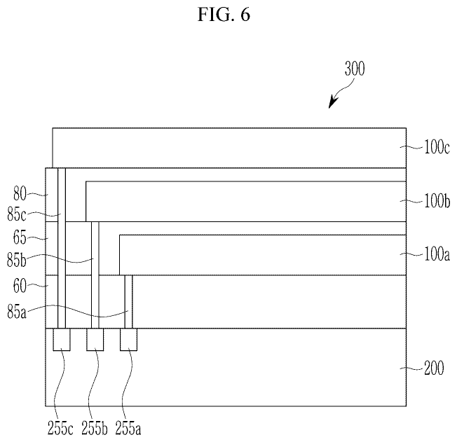

FIG. 5 is a perspective view showing another example of an image sensor according to some example embodiments and FIG. 6 is a cross-sectional view showing an example of the image sensor of FIG. 5 according to some example embodiments. FIG. 6 may be a cross-sectional view along view line VI-VI′ in FIG. 5 according to some example embodiments.

The image sensor 300 according to some example embodiments, including the example embodiments shown in FIGS. 5 and 6, has a structure in which a green sensor configured to selectively absorb light in the green wavelength region, a blue sensor configured to selectively absorb light in the blue wavelength region, and a red sensor configured to selectively absorb light in the red wavelength region are stacked.

The image sensor 300 according to some example embodiments, including the example embodiments shown in FIGS. 5 and 6, includes a semiconductor substrate 200, a lower insulation layer 60, an intermediate insulation layer 65, an upper insulation layer 80, a first sensor 100a, a second sensor 100b, and a third sensor 100c.

The semiconductor substrate 200 may be a semiconductor substrate such as a silicon substrate, and a transfer transistor (not shown) and charge storages 255a, 255b, and 255c are integrated therein.

A metal wire (not shown) and a pad (not shown) are formed on the semiconductor substrate 200, and a lower insulation layer 60 is formed on the metal wire and the pad.

The first sensor 100a, the second sensor 100b, and the third sensor 100c are formed on the lower insulation layer 60 in that order.

At least one of the first, second, or third sensors 100a, 100b, or 100c may be the aforementioned sensor 100. One of the anode 110 or the cathode 120 of the first, second, and third sensors 100a, 100b, and 100c may be a light-receiving electrode, and the other of the anode 110 or the cathode 120 of the first, second, and third sensors 100a, 100b, and 100c may be connected to the charge storages 255a, 255b, and 255c.

The first sensor 100a may be configured to selectively absorb light in any one of red, blue, or green wavelength regions and perform photoelectric conversion. For example, the first sensor 100a may be a red sensor. The intermediate insulation layer 65 is formed on the first sensor 100a. The intermediate insulation layer 65 may be made of an inorganic insulating material such as a silicon oxide and/or a silicon nitride, or a low dielectric constant (low K) material such as SiC, SiCOH, SiCO, and SiOF.

The second sensor 100b is formed on the intermediate insulation layer 65. The second sensor 100b may be configured to selectively absorb light in any one of red, blue, or green wavelength spectra and perform photoelectric conversion. For example, the second sensor 100b may be a blue sensor.

The upper insulation layer 80 is formed on the second sensor 100b. The lower insulation layer 60, intermediate insulation layer 65, and upper insulation layer 80 have a plurality of trenches 85a, 85b, and 85c exposing charge storages 255a, 255b, and 255c.

The third sensor 100c is formed on the upper insulation layer 80. The third sensor 100c may be configured to selectively absorb light in any one of red, blue, or green wavelength regions and perform photoelectric conversion. For example, the third sensor 100c may be a green sensor.

Focusing lens (not shown) may be further formed on the third sensor 100c. The focusing lens may control a direction of incident light and gather the light in one region. The focusing lens may have a shape of, for example, a cylinder or a hemisphere, but is not limited thereto.

In FIGS. 5 and 6, a structure in which the first sensor 100a, the second sensor 100b, and the third sensor 100c are sequentially stacked is shown, but the stacking order is not limited to this and may vary.

As described above, by having a stacked structure of the first sensor 100a, the second sensor 100b, and the third sensor 100c configured to absorb light in different wavelength regions, the size of the image sensor is further reduced, implementing a miniaturized image sensor.

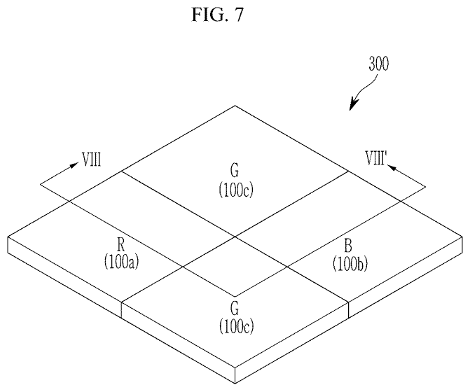

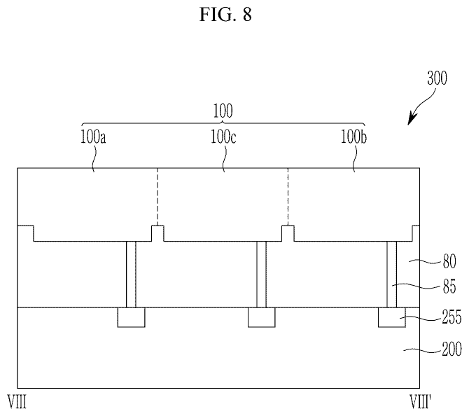

FIG. 7 is a perspective view showing another example of an image sensor according to some example embodiments and FIG. 8 is a cross-sectional view showing an example of the image sensor of FIG. 7 according to some example embodiments. FIG. 8 may be a cross-sectional view along view line VIII-VIII′ in FIG. 7.

Referring to FIGS. 7 and 8, the image sensor 300 includes a sensor 100 on a semiconductor substrate 200, and the sensor 100 includes first, second, and third sensors 100a, 100b, and 100c. The first, second, and third sensors 100a, 100b, and 100c may be configured to convert light in different wavelength ranges (e.g., blue light, green light, or red light) from each other into electrical signals.

Referring to FIG. 8, the first, second, and third sensors 100a, 100b, and 100c are arranged in a direction parallel to the surface of the semiconductor substrate 200 (e.g., in the direction of the surface of the semiconductor substrate 200), unlike the aforementioned example. Each of the first, second, and third sensors 100a, 100b, and 100c is electrically connected to the charge storage 255 integrated in the semiconductor substrate 200 through the trench 85.

The aforementioned sensor 100 or image sensor 300 may be included in various electronic devices. Electronic devices such as display devices may be applied to, for example, mobile phones, video phones, smart phones, mobile phones, smart pads, smart watches, digital cameras, tablet PCs, laptop PCs, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT), Internet of all things (IoE), drones, door locks, safes, automatic teller machines (ATM), security devices, medical devices, or automotive electronic components, but are not limited thereto.

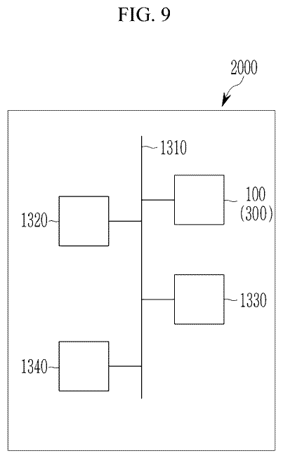

FIG. 9 is a schematic view illustrating an example of a configuration of an electronic device according to some example embodiments.

Referring to FIG. 9, the electronic device 2000 further includes a bus 1310, a processor 1320, a memory 1330, and at least one additional device 1340 in addition to the aforementioned sensor 100 or image sensor 300. Information of the aforementioned sensor 100 or image sensor 300, processor 1320, memory 1330, and at least one additional device 1340 may be transferred to each other through the bus 1310.

The processor 1320 may include processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), or the like. As an example, the processing circuitry may include a non-transitory computer readable storage device. The processor 1320 (e.g., a central processing unit or CPU) may, for example, control an operation of the sensor 100 or the image sensor 300, for example based on executing an instruction program stored at the memory 1330 (e.g., a solid-state drive (SSD) storage device).

The memory 1330 may store an instruction program, and the processor 1320 may perform a function related to the sensor 100 or image sensor 300 based on executing the instruction program.

The at least one additional device 1340 may be one or more communication interfaces (e.g., wireless communication interfaces, wired interfaces), user interfaces (e.g., keyboard, mouse, buttons, etc.), power supply and/or power supply interfaces, or any combination thereof.

The units and/or modules described herein may be implemented using hardware constituent elements and software constituent elements. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner.

The software and data may be stored by one or more non-transitory computer readable storage devices.

The method according to some example embodiments may be recorded in a non-transitory computer readable storage device including program instructions for implementing various operations of the aforementioned embodiments. The storage device may also include program instructions, data files, data structures, and the like alone or in combination. The program instructions recorded in the storage device may be specially designed for some example embodiments or may be known to those skilled in computer software and available for use. Examples of non-transitory computer-readable storage devices may include magnetic media such as hard disks, floppy disks, and magnetic tapes; optical media such as CD-ROM discs, DVDs and/or blue-ray discs; magneto-optical media such as optical disks; and a hardware device configured to store and execute program instructions such as ROM, RAM, flash memory, and the like. The aforementioned device may be configured to operate as one or more software modules to perform the operations of the aforementioned example embodiments.

Hereinafter, some example embodiments are illustrated in more detail with reference to examples. However, the scope of the inventive concepts is not limited to these examples.

### PREPARATION EXAMPLES

### Preparation Example 1

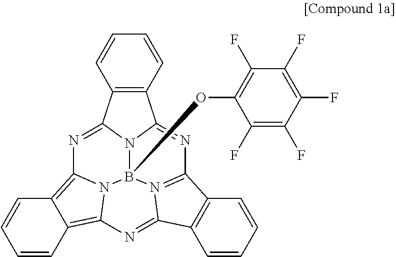

Compound 1a (pentafluorophenoxyboronsub-phthalocyanine, pentafluorophenoxyboronsubphthalocyanine, F5-SubPc) is prepared by purchasing it from Luminescence Technology Corp.

### Preparation Example 2

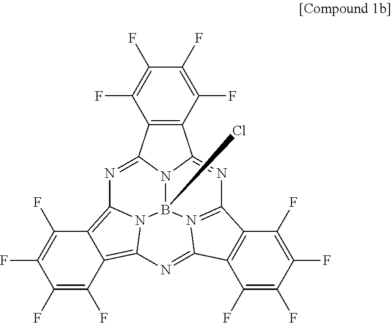

Compound 1b (dodecafluoro subphthalocyanatoboron (III) chloride) is prepared by purchasing it from AnyCHEM, Co. Ltd.

### Preparation Example 3

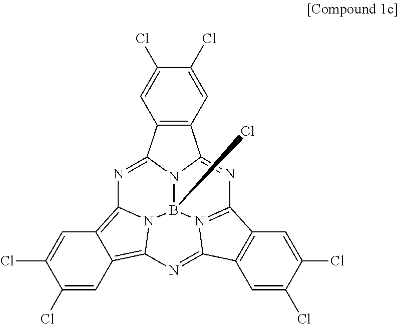

Compound 1c (2,3,9,10,16,17-hexachlorinated boron subphthalocyanine chloride, C16-SubPc) is prepared by purchasing it from Luminescence Technology Corp.

### Preparation Example 4

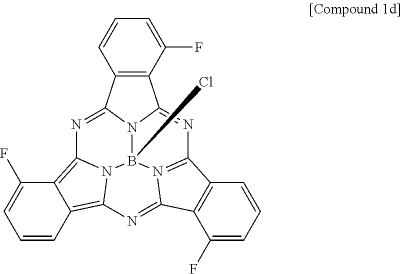

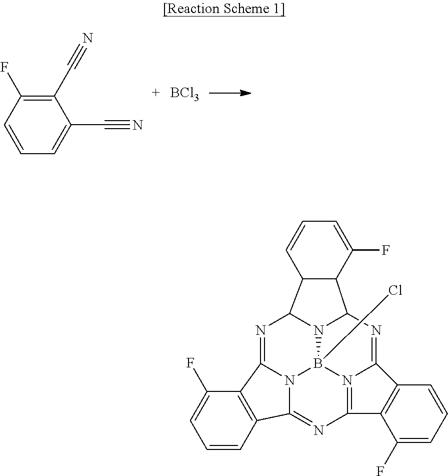

After adding boron trichloride (BCl3) (50 mmol, a 1 M xylene solution) to a chlorobenzene (100 ml) suspension of 3-fluorophthalonitrile (50 mmol, 7.31 g), the mixture is stirred at 150° C. for 30 minutes under a nitrogen atmosphere. After cooling to room temperature, 1.75 g of Compound 1 d is obtained by silica-filtering in a volume ratio of toluene:ethylacetate=1:9.

¹H-NMR (500 MHz, CD₂Cl₂): δ 7.35-7.30 (m, 6H), 7.20 (m, 3H).

### Preparation Example 5

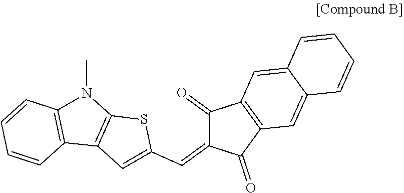 [SMILES: Cn1c2ccccc2c2cc(C=C3C(=O)c4cc5ccccc5cc4C3=O)sc21]

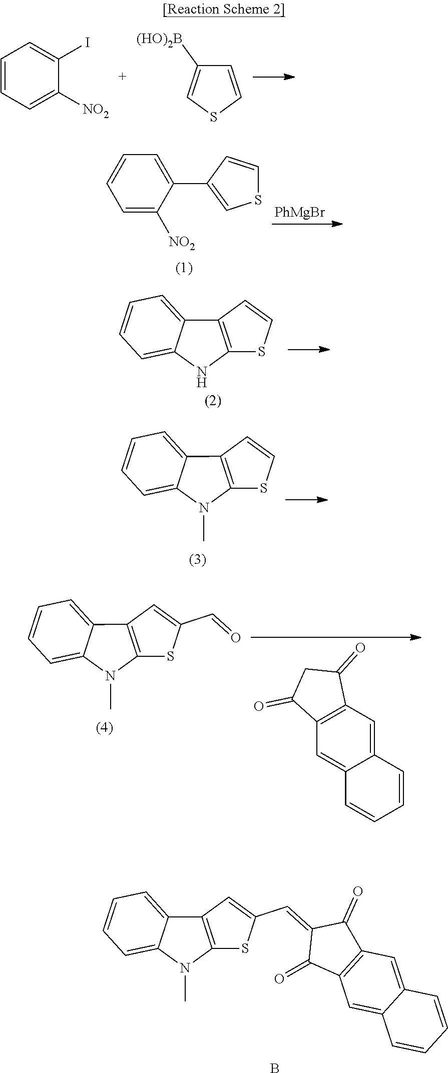

### (3) (i) Synthesis of Compound (1)

2.5 g (10.0 mmol) of 1-iodo-2-nitrobenzene, 1.67 g (13 mmol) of thiophene-3-yl boronic acid, and 0.58 g (0.5 mmol) of tetrakis(triphenylphosphine)palladium (0) are dissolved in 50 ml of DMF and 50 ml of water and then, reacted at 90° C. for 12 hours. Subsequently, a product obtained therefrom through extraction with dimethylether at room temperature is separated and purified through silica gel column chromatography (ethylacetate:hexane=1:8 in a volume ratio) to obtain 1.82 g (a yield: 88.6%) of Compound (1).

### (ii) Synthesis of Compound (2)

4.0 g (19.5 mmol) of 3-(2-nitrophenyl)thiophene is dissolved in 250 ml of dry THE and cooled to 0° C., and 18.9 ml (59.5 mmol) of phenylmagnesium bromide (PhMgBr) (1.0 M in a THE solution) is slowly added dropwise thereto. During the addition over 10 minutes, the internal solution is maintained not to exceed 3° C. After a reaction at 0° C. for 5 minutes, 50 ml of a NH4Cl saturated solution is added thereto. Subsequently, after adding 500 ml of water thereto, an organic layer therefrom is washed with a sodium chloride aqueous solution, three times extracted with ethyl acetate, and dried by adding anhydrous magnesium sulfate thereto. The obtained product is separated and purified through silica gel column chromatography (ethylacetate:hexane=1:5 in a volume ratio) to obtain 2.88 g (a yield: 85.2%) of 8H-thieno[2,3-b]indole (Compound (2)).

### (iii) Synthesis of Compound (3)

2.5 g (14.4 mmol) of 8H-thieno[2,3-b]indole and 8.10 g (144.3 mmol) of potassium hydroxide are dissolved in 50 ml of dimethyl sulfoxide, and 6.13 g (43.2 mmol) of iodomethane is added dropwise thereto. The obtained mixture is stirred at 30° C. Subsequently, the resultant is added to 250 ml of water and then, extracted with dichloromethane. The obtained product is dried with anhydrous magnesium sulfate and separated and purified through silica gel column chromatography (hexane:dichloromethane=5:1 in a volume ratio) to obtain 2.29 g (a yield 85.2%) of 8-methyl-8H-thieno[2,3-b]indole (Compound (3)).

### (iv) Synthesis of Compound (4)

2.4 ml of phosphoryl chloride is added dropwise to 15.0 ml of N,N-dimethyl formamide at −15° C. and then, stirred at room temperature for 2 hours. The resultant is slowly added to a mixture of 100 ml of dichloromethane and 1.0 g of Compound (3) at −15° C. and then, stirred at room temperature for 30 minutes and concentrated under a reduced pressure. After adding 150 ml of water thereto, an aqueous sodium hydroxide solution is added thereto until pH becomes 14 and then, stirred at room temperature (24° C.) for 2 hours. Subsequently, an organic layer is extracted therefrom with dichloromethane, washed with an aqueous sodium chloride solution, and dried with anhydrous magnesium sulfate. The obtained product is separated and purified through silica gel column chromatography (hexane:ethyl acetate=4:1 in a volume ratio) to obtain 1.12 g (a yield: 98.0%) of 8-methyl-8H-selenopheno[2,3-b]indole-2-carbaldehyde (Compound (4)).

### (v) Synthesis of Compound B

0.7 g (3.25 mmol) of Compound (4) is suspended in ethanol, and 0.70 g (3.58 mmol) of 1 H-cyclopenta[b]naphthalene-1,3(2H)-dione is added thereto and then, reacted at 50° C. for 2 hours to obtain 1.08 g (a yield: 84.7%) of Compound B.

Compound B is purified by sublimation to purity of 99.9%.

¹H-NMR (500 MHz, Methylene Chloride-d2): δ 8.8 (d, 2H), 8.5 (s, 1H), 8.2 (m, 2H), 8.1 (d, 1H), 7.9 (s, 1H), 7.8 (m,2H), 7.6 (d, 1H), 7.3 (m, 2H), 3.7 (s, 3H).

### Evaluation I

The compounds according to Preparation Examples 1 to 4 are evaluated with respect to light absorption characteristics and electrical characteristics.

The light absorption characteristics are evaluated by thermally depositing each of the compounds according to Preparation Examples 1 to 4 at 0.5 Å/s to 1.0 Å/s under a high vacuum (<10⁻⁷ Torr) to form a 30 nm-thick thin film and irradiating ultraviolet rays-visible rays (UV-Vis) to the thin film with a UV-Vis spectrometer (Shimadzu Corp.).

A HOMO energy level is evaluated by irradiating UV light to the thin film with AC-2 (Hitachi Ltd.) or AC-3 (Riken Keiki Co., LTD.) to measure a dose of photoelectrons emitted according to energy.

An energy bandgap is obtained by using a UV-Vis spectrometer (Shimadzu Corp.).

A LUMO energy level is calculated by using the energy bandgap and the HOMO energy level.

The results are shown in Table 1.

TABLE 1

| | λ_{max, A} (nm) | HOMO (eV) | LUMO (eV) | Eg (eV) |
|---|---|---|---|---|
| Compound 1a | 575 | 5.59 | 3.54 | 2.05 |
| Compound 1b | 580 | 6.15 | 4.15 | 2.00 |
| Compound 1c | 580 | 6.01 | 4.03 | 1.98 |
| Compound 1d | 605 | 6.00 | 4.06 | 1.94 |

* λ_{max, A}: maximum absorption wavelength
* Eg: energy bandgap

### EXAMPLES

### Example 1

ITO (work function(WF): 4.7 eV) is sputtered on a glass substrate to form a 150 nm-thick anode, and molybdenum oxide (MoOx, 0<x≤3) (WF: 5.4 eV) is deposited thereon to form a 30 nm-thick hole auxiliary layer. Subsequently, on the hole auxiliary layer, a 50 nm-thick organic photoelectric conversion layer is formed by depositing Compound 1 a according to Preparation Example 1 (HOMO: 5.59 eV, LUMO: 3.54 eV, Eg: 2.05 eV) alone at 0.35 Å/s under vacuum of 10⁻⁷ Torr at 171° C. On the organic photoelectric conversion layer, a 100 nm-thick cathode is formed by depositing aluminum (AI) (WF: 4.3 eV), manufacturing a sensor.

### Reference Example 1-1

A sensor is manufactured in the same manner as in Example 1 except that a 60 nm-thick organic photoelectric conversion layer is formed by co-depositing Compound B according to Preparation Example 5 (p-type semiconductor, HOMO: 5.73 eV, LUMO: 3.66 eV) and Compound 1a according to Preparation Example 1 (n-type semiconductor) in a volume ratio of 1:1 instead of Compound 1a according to Preparation Example 1 alone.

### Reference Example 1-2

A sensor is manufactured in the same manner as in Example 1 except that a bilayer organic photoelectric conversion layer of a 10 nm-thick p-type layer formed by depositing Compound B according to Preparation Example 5 (p-type semiconductor, HOMO: 5.73 eV, LUMO: 3.66 eV) and a 50 nm-thick n-type layer formed by depositing Compound 1 a according to Preparation Example 1 (n-type semiconductor) in a volume ratio of 1:1 instead of Compound 1 a according to Preparation Example 1 alone is formed.

### Example 2

A sensor is manufactured in the same manner as in Example 1 except that an organic photoelectric conversion layer is formed by depositing Compound 1 b according to Preparation Example 2 alone instead of Compound 1a according to Preparation Example 1 alone.

### Reference Example 2-1

A sensor is manufactured in the same manner as in Example 2 except that a 60 nm-thick organic photoelectric conversion layer is formed by co-depositing Compound 5 (p-type semiconductor) according to Preparation Example 5 and Compound 1 b according to Preparation Example 2 in a volume ratio of 1:1 instead of Compound 1 b according to Preparation Example 2 alone.

### Reference Example 2-2

A sensor is manufactured in the same manner as in Example 2 except that a bilayer organic photoelectric conversion layer of a 10 nm-thick p-type layer formed by depositing Compound B (p-type semiconductor) according to Preparation Example 5 and a 50 nm-thick n-type layer formed by depositing Compound 1 b according to Preparation Example 2 is formed instead of Compound 1 b according to Preparation Example 2 alone.

### Evaluation II

The sensors according to the Examples and the Reference Examples are evaluated with respect to electrical characteristics.

The electrical characteristics are evaluated from an external quantum efficiency (EQE) spectrum and response characteristics according to time (transient response time).

The external quantum efficiency (EQE) spectrum is evaluated by using Incident Photon to Current Efficiency (IPCE) equipment at 3 V, and a full width at half maximum (FWHM_{EQE}) of the external quantum efficiency is a width corresponding to a half of external quantum efficiency at a wavelength (λ_{max,EQE}) representing maximum external quantum efficiency (EQEₘₐₓ) in the external quantum efficiency (EQE) spectrum.

The response characteristics according to time are evaluated by transient response time, and the transient response time is photodetection time detected by supplying light to the sensors under a reverse bias. Herein, 12 Luxeon Star/O (LXHL-NWE8) white LEDs is used as a light source, Oscilloscopt (Tektronic TDS 3032B) is used to record transient signals, and Keithley2400 is used as a bias source, wherein all measurement parts are controlled by Wavetrics IGOR Pro Software.

The results are shown in Tables 2 and 3. Gh,T

TABLE 2

| | | | Transient Response | |
|---|---|---|---|---|
| | EQE-3V | | Time (μs) | |
| | λ_{max, EQE} (nm) | FWHM_{EQE} (nm) | @ 0 V | @ 5 V |
| Example 1 | 584 | 68.3 | 30 | 18 |
| Reference | 580 | 144.0 | N/A | 29 |
| Example 1-1 | | | | |
| Reference | 581 | 14.21 | 50 | 24.5 |
| Example 1-2 | | | | |

TABLE 3

| | | | Transient Response | |
|---|---|---|---|---|
| | EQE-3V | | Time (μs) | |
| | λ_{max, EQE} (nm) | FWHM_{EQE} (nm) | @ 0 V | @ 5 V |
| Example 2 | 588 | 90.1 | 8 | 4.4 |
| Reference | 589 | 150.62 | 11 | 4.5 |
| Example 2-1 | | | | |
| Reference | 584 | 139.65 | 68 | 4.3 |
| Example 2-2 | | | | |

* λ_{max, EQE}: wavelength exhibiting maximum external quantum efficiency (EQE)
* FWHM_{EQE}: full width at half maximum (FWHM) of external quantum efficiency

(EQE) spectrum

Referring to Tables 2 and 3, the sensors according to Examples 1 and 2, compared with the sensors according to Reference Examples 1-1, 1-2, 2-1, and 2-2, exhibit a narrow full width at half maximum (FWHM) of an external quantum efficiency (EQE) spectrum and equivalent or improved reaction time. Accordingly, the sensors according to Examples 1 and 2, compared with sensors including heterogeneous semiconductors, exhibit improved electrical characteristics in the narrow wavelength region.

While the inventive concepts have been described in connection with what is presently considered to be practical example embodiments, it is to be understood that is the inventive concepts are not limited to such example embodiments. On the contrary, the inventive concepts are intended to cover various modifications and equivalent arrangements included within the spirit and scope of the appended claims.

What is claimed is:

1. A sensor, comprising:
an anode;
a cathode;
an organic photoelectric conversion layer, the organic photoelectric conversion layer between the anode and the cathode, the organic photoelectric conversion layer including one type of organic light absorption semiconductor as a photoelectric conversion material and not including any other type of organic light absorption semiconductor of a different type of organic light absorption semiconductor, the one type of organic light absorption semiconductor is one of a p-type organic light absorption semiconductor or an n-type organic light absorption semiconductor; and
a hole auxiliary layer, the hole auxiliary layer between the anode and the organic photoelectric conversion layer, the hole auxiliary layer including a hole auxiliary material,
wherein an energy bandgap of the organic light absorption semiconductor is about 1.90 to about 2.20 eV,
wherein a highest occupied molecular orbital (HOMO) energy level of the organic light absorption semiconductor is a same or deeper energy level in relation to a HOMO energy level of the hole auxiliary material, a difference between the HOMO energy level of the organic light absorption semiconductor and the HOMO energy level of the hole auxiliary material in a range of greater than 0 eV and less than about 1.00 eV, and
a difference between a work function of the cathode and a lowest unoccupied molecular orbital (LUMO) energy level of the organic light absorption semiconductor is less than about 1.00 eV.

2. The sensor of claim 1, wherein the organic photoelectric conversion layer is a single layer formed of the organic light absorption semiconductor.

3. The sensor of claim 1, wherein
the sensor further comprises an electron auxiliary layer between the cathode and the organic light absorption semiconductor, the electron auxiliary layer including an electron auxiliary material, and
a difference between a LUMO energy level of the electron auxiliary material and the LUMO energy level of the organic light absorption semiconductor is less than about 1.00 eV.

4. The sensor of claim 1, wherein the sensor is configured to exhibit a maximum external quantum efficiency (EQE) at a wavelength of about 500 nm to about 610 nm.

5. The sensor of claim 1, wherein a full width at half maximum of an external quantum efficiency (EQE) spectrum at 3V of the sensor is about 30 nm to about 100 nm.

6. The sensor of claim 1, wherein the one type of organic light absorption semiconductor includes an organic light absorption semiconductor that is represented by Chemical Formula 1: 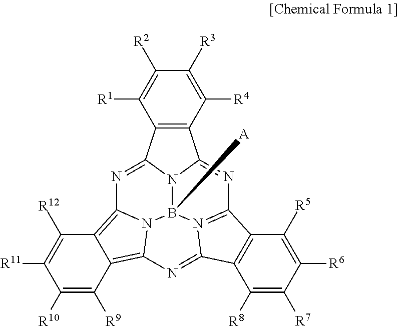
wherein, in Chemical Formula 1,
R¹ to R¹² are each independently hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C6 to C30 aryloxy group, a substituted or unsubstituted C₃ to C30 heterocyclic group, a cyano group, a halogen, a halogen-containing group, or any combination thereof, and
A is a halogen, a halogen-containing group, a substituted or unsubstituted C1 to C30 alkoxy group, a substituted or unsubstituted C6 to C30 aryloxy group, or any combination thereof.

7. The sensor of claim 6, wherein at least one of R¹, R², R³, R⁴, R⁵, R⁶, R⁷, R⁸, R⁹, R¹⁰, R¹¹, R¹², or A is a halogen or a halogen-containing group.

8. The sensor of claim 6, wherein R¹ to R¹² are each independently fluorine or a fluorine-containing group.

9. The sensor of claim 6, wherein A is a fluorine-substituted phenoxy group.

10. A sensor, comprising:
an anode;
a cathode; and
an organic photoelectric conversion layer between the anode and the cathode, the organic photoelectric conversion layer formed of an organic light absorption semiconductor represented by Chemical Formula 1: 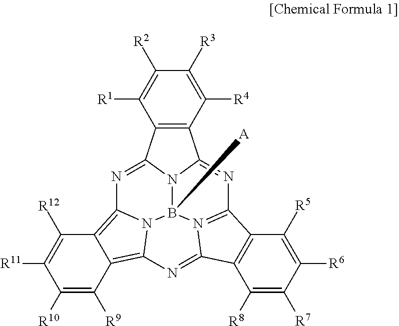
wherein, in Chemical Formula 1,
R¹ to R¹² are each independently hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C6 to C30 aryloxy group, a substituted or unsubstituted C₃ to C30 heterocyclic group, a cyano group, a halogen, a halogen-containing group, or any combination thereof, and
A is a halogen, a halogen-containing group, a substituted or unsubstituted C1 to C30 alkoxy group, a substituted or unsubstituted C6 to C30 aryloxy group, or any combination thereof.

11. The sensor of claim 10, wherein the organic photoelectric conversion layer does not comprise any counterpart semiconductor for any pn junction with the organic light absorption semiconductor.

12. The sensor of claim 10, wherein the organic photoelectric conversion layer is a single layer formed of a single continuous phase of the organic light absorption semiconductor.

13. The sensor of claim 10, wherein at least one of R¹, R², R³, R⁴, R⁵, R⁶, R⁷, R⁸, R⁹, R¹⁰, R¹¹, R¹², or A is a halogen or a halogen-containing group.

14. The sensor of claim 10, wherein R¹ to R¹² are each independently fluorine or a fluorine-containing group.

15. The sensor of claim 10, wherein A is a fluorine-substituted phenoxy group.

16. The sensor of claim 11, wherein
the sensor further comprises a hole auxiliary layer, the hole auxiliary layer between the anode and the organic photoelectric conversion layer, the hole auxiliary layer including a hole auxiliary material, and
a HOMO energy level of the organic light absorption semiconductor is a same energy level or a deeper energy level in relation to a HOMO energy level of the hole auxiliary material, a difference between the HOMO energy level of the organic light absorption semiconductor and the HOMO energy level of the hole auxiliary material in a range of greater than 0 eV and less than about 1.00 eV.

17. The sensor of claim 10, wherein a difference between a work function of the cathode and a lowest unoccupied molecular orbital (LUMO) energy level of the organic light absorption semiconductor is less than about 1.00 eV.

18. The sensor of claim 10, wherein
the sensor further comprises an electron auxiliary layer between the cathode and the organic light absorption semiconductor, the electron auxiliary layer including an electron auxiliary material, and
a difference between a LUMO energy level of the electron auxiliary material and a LUMO energy level of the organic light absorption semiconductor is less than about 1.00 eV.

19. An electronic device comprising the sensor of claim 1.

20. An electronic device comprising the sensor of claim 10.
